(19) United States
(12) Patent Application Publication
(10) Pub. No.: US 2005/0156264 A1
(43) Pub. Date: Jul. 21, 2005

(54) Solid image pickup apparatus

(75) Inventors: Yorito Sakano, Sakata-shi (JP); Akira Mizuguchi, Turioka-shi (JP)

Correspondence Address: EDWARDS & ANGELL, LLP, P.O. BOX 55874, BOSTON, MA, 02205, US

(73) Assignee: Seiko Epson Corporation

(21) Appl. No.: 11/030,479

(22) Filed: Jan. 5, 2005

(30) Foreign Application Priority Data
Jan. 5, 2004 (JP) 2004-000358

(51) Int. Cl. H01L 31/0232

(52) U.S. Cl. 257/432

(57) ABSTRACT

In a solid image pickup apparatus including an opto-electrical element and a transistor TM formed adjacent to the opto-electrical element, the solid image pickup apparatus comprises: a single conductive substrate 1; a first well 21 of an inverse conductive type formed on the substrate 1 of an opto-electrical element forming area; a second well of a single conductive type formed on the first well 21: a third well 21′ of the inverse conductive type formed on the substrate 1 of a forming area of the transistor and formed adjacent to the first well 21; a fourth well 5 of the single conductive type formed on the third well 21′ and formed adjacent to the second well 4; a gate electrode 6 formed over the fourth well 5, having an opening; a source 7 formed below the opening; a drain 8 formed apart from the source 7 and electrically connected to the third well 21′; and a first diffusion layer 28 of the single conductive type formed below the gate electrode 6 and below the opening.

### BACKGROUND OF THE INVENTION

1. Field of the Invention

The present invention relates to a solid image pickup apparatus having a high picture quality characteristic and a low power consumption characteristic.

2. Related Art

As solid image pickup apparatus mounted in mobile phones and the like, there are an image sensor of a CCD (Charge Coupled Device) type and an image sensor of a CMOS type. The image sensor of the CCD type excels in picture quality, while the image sensor of the CMOS type has small power consumption with low process cost. In recent years, there has been proposed a MOS type solid image pickup apparatus of a threshold voltage modulation system which has both high picture quality and low power consumption. In regard to the MOS type solid image pickup apparatus of the threshold voltage modulation system, for example, it is disclosed in Japanese Unexamined Patent Publication No. 2001-177085 (JP '085).

The image sensor obtains image output by arraying sensor cells in a matrix pattern and repeating three phases of initialization, storage, and read-out. The image sensor disclosed by JP '085 is such that each unit pixel has a light receiving diode to perform storage and a transistor to perform read-out.

FIG. 11 is a schematic section of the image sensor disclosed in JP '085.

In the image sensor in FIG. 11, a light receiving diode 111 and an insulating gate field effect transistor 112 are adjacently arranged per unit pixel on a substrate 100. A gate electrode 113 of the transistor 112 is formed in a ring shape, and a source area 114 is formed in a central opening portion of the gate electrode 113. In the vicinity of the gate electrode 113, there is formed a drain area 115.

An electric charge (light generating charge) generated by incident light from an opening area of the light receiving diode 111 is transferred to a p-type well area 116 below the gate electrode 113 and stored in a carrier pocket 117 formed in this part. Threshold voltage of the transistor 112 changes due to light generating charges store d in the carrier pocket 117. This enables a signal (pixel signal) corresponding to the incident light to be fetched from the source area 114 of the transistor 112.

It should be noted that in the apparatus of JP '085, an output of the unit pixel arrayed in the same column is designed such that it can be fetched through a common source line. By controlling a voltage to be impressed on the gate of the transistor 112 per line, it is made possible to make a selective read-out from the unit pixel of a specified line of each unit pixel connected to the common source line. Namely, a relatively high gate voltage is impressed on the transistor 112 of the unit pixel (selective pixel) to be read out while a relatively low gate voltage is impressed on the unit pixel of the transistor 112 which does not perform other read-out. The output of the transistor on which the high gate voltage is impressed is higher than the output of the transistor on which the low gate voltage is impressed, thus making it possible to obtain an output of a selective pixel from the source line.

Incidentally, in a forming process of the source area 114 of a unit pixel of FIG. 11, as an impurity, for example, phosphor is injected. But, since phosphor has a high diffusion coefficient, through ion implantation to form the source area, phosphor is diffused to even part of (slant area) of the well area 116 below the source area 114. Namely, the well area 116 is eroded by the source area 114, so that in an area 122 surrounded by broken lines of an eroded portion and its adjacent portion, a junction field effect transistor (hereinafter to be referred to also as “Junction FET”) may be formed.

It should be noted that by injecting an impurity of a large mass number such as arsenic, it is possible to form a shallow source area, whereas, because, in this case, an extremely heavy damage may be caused when injecting, an impurity of a large mass number may not be used in forming the source area.

FIG. 12 is an explanatory diagram showing an equivalent circuit of the unit pixel of FIG. 11. The drain area 115 in the vicinity of the gate electrode 113 and an n-type diffusion layer 118 are electrically connected, and there is formed a leak path from the drain area 115 to the n-type diffusion layer 118 as shown in FIG. 12. Between the n-type diffusion layer 118 and the source area 114, a JFET (junction transistor Tr₁ of FIG. 12) is formed.

FIG. 13 is a graph showing a concentration distribution in the source area 114 and the well area 116 therebelow, with the axis of abscissa representing substrate depth and the axis of ordinate representing concentration of impurities.

A curve a of FIG. 13 shows a distribution of concentration of an impurity through injection of the impurity at the time of forming the well area 116. The curve a shows that the impurity was injected to a depth corresponding to a position of forming the well area 116 which is slightly separated from the substrate surface. As a result of this, the concentration of the impurity in the vicinity of the diffusion layer 118 of the well region 116 assumes a relatively high value.

A curve b shows a distribution of concentration of an impurity through injection of the impurity at the time of forming the source area 114. However, as mentioned above, the impurity diffuses to a relatively deep area through injection of the impurity at the time of forming the source area. By this means, the distribution of concentration of the impurity in the source area 114 changes to what is indicated by a curve c of FIG. 13. As apparent from comparisons to the curves a and c, the well area 116 in the area below the source area 114 is such that its concentration diminishes due to an influence of the impurity for formation of the source area.

It should be noted that such erosion due to the source area 114 does not occur in the well area 116 of an area other than below the source area 1124. Namely, while the carrier pocket 117 formed directly below the gate electrode 113 and the well area 116 therebelow are formed for p-type having high concentration, the well area 116 below the source region 114 is eroded, and the junction FET is formed of the eroded portion and the well area 116 of the high concentration adjacent thereto.

As the curve c shows, there is a significant decrease of the potential barriers in the well area of 116 below the source area 114, so that even in a case of the transistor 112 being not in continuity, there is continuity in the junction FET (Tr₁) to put the leak path 125 from the drain area 115 to the source area 114 in the state of continuity. In this manner, even in the case of the transistor 112 not in continuity, the leak path 125 due to the JFET is formed between the drain area 115 and the source area 114.

As a result, the characteristics of the transistor 112 are subject to effect of a leak current in an area where a gate voltage Vg is at a relatively low level. Due to the effect of the leak current, the output of the non-selective pixel increases such that it becomes impossible to detect an accurate amount of light received. For example, there was a problem in which a noise of longitudinal striations (hereafter referred to as “black smear”) shown in black due to an influence of an incident ray of this intense light.

### SUMMARY OF THE INVENTION

The present invention has been made in view of such problem. It is one object to provide a solid image pickup apparatus which can prevent a junction transistor from being formed, improve the characteristics of the modulation transistor, and achieve high picture quality.

In a solid image pickup apparatus according to one embodiment of the present invention which includes an opto-electrical element and a transistor formed adjacent to the opto-electrical element, the solid image pickup apparatus comprises: a single conductive substrate; a first well of an inverse conductive type formed on the substrate of an opto-electrical element forming area; a second well of the single conductive type formed on the first well: a third well of the inverse conductive type formed on the substrate of a forming area of the transistor and formed adjacent to the first well; a fourth well of the single conductive type formed on the third well and formed adjacent to the second well; a gate electrode formed over the fourth well, having an opening; a source formed below the opening; a drain formed apart from the source and electrically connected to the third well; and a first diffusion layer of the single conductive type formed below the gate electrode and below the opening.

According to such configuration, a light generating charge generated in the first well of the opto-electric element forming area is transferred from the first well to the fourth well. A threshold voltage of a channel of the transistor is controlled by a light generating charge held in the fourth well, and a pixel signal corresponding to the light generating charge is outputted from the transistor. The source area of the transistor is constituted by the inverse conductive type, and the fourth well of the single conductive type and the third well of the inverse conductive type are formed in the transistor forming area. However, over the third well and below the gate electrode and below the opening, there is formed the first diffusion layer of the single conductive type. By means of this first diffusion layer, it is possible to prevent a junction field effect transistor from being formed due to a concentration change in the fourth well, and, through the potential barrier due to the diffusion layer, it is possible to prevent formation of a path of leak current from the third well to the source area. This enables high picture quality to be attained; for example, generation of a black smear may be prevented.

Further, the first diffusion layer comprises the potential barrier of a current path from the third well to the source.

According to such configuration, it is possible to prevent generation of a leak current by raising the potential barrier below the source area.

Further, the first diffusion layer is characterized by formation of a concentration in excess of substantially the same concentration as the concentration of the third well.

According to such configuration, the concentration of the first diffusion layer is sufficiently high, so that a flow of the leak current may be prevented by raising the potential barrier to the current path from the third well to the source area.

### BRIEF DESCRIPTION OF THE DRAWINGS

FIG. 1 is a sectional view showing a sectional shape of a solid image pickup apparatus according to a first embodiment of the present invention:

FIG. 2 is a plan view showing a planar shape of one sensor cell of a solid image pickup apparatus according to the first embodiment of the present invention;

FIG. 3 is a circuit block diagram showing the entire structure of an element through an equivalent circuit;

FIG. 4 is a graph for explaining causes of generation of a black smear;

FIG. 5 is a graph for explaining a concentration distribution in the source area 114 and the well area 116 therebelow, with the axis of abscissa representing substrate depth and the axis of ordinate representing concentration of impurities;

FIG. 6 is a graph showing characteristics of a modulation transistor in a solid image pickup apparatus in the present embodiment;

FIG. 7 presents process diagrams for explaining a manufacturing process of an element;

FIG. 8 presents process diagrams for explaining the manufacturing process of an element;

FIG. 9 is an explanatory diagram for explaining the manufacturing process according to a second embodiment of the present invention;

FIG. 10 is an explanatory diagram for explaining the manufacturing process according to a second embodiment of the present invention;

FIG. 11 is a schematic section showing an image sensor disclosed in Japanese Unexamined Patent Publication No. 2001-177085;

FIG. 12 is an explanatory diagram showing an equivalent circuit of a unit pixel of FIG. 11; and

FIG. 13 is a graph showing a concentration distribution in the source area 114 and the well area 116 therebelow, with the axis of abscissa representing substrate depth and the axis of ordinate representing concentration of impurities.

### DETAILED DESCRIPTION OF THE PREFERRED EMBODIMENTS

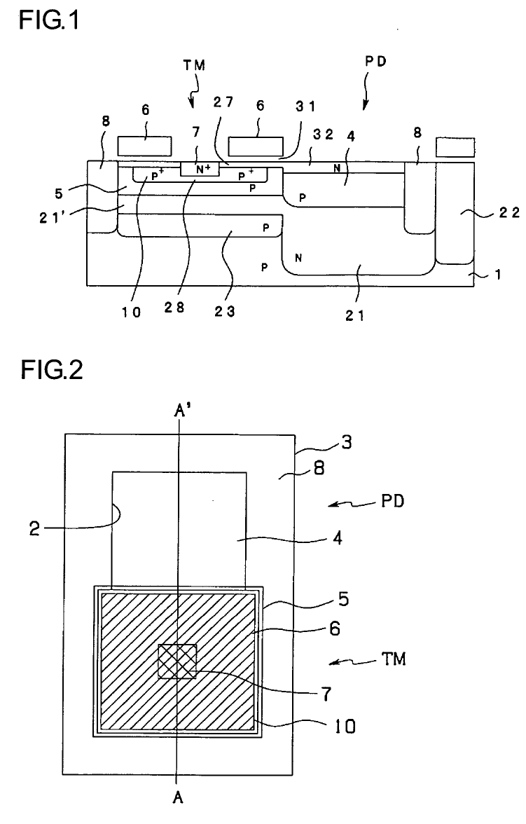

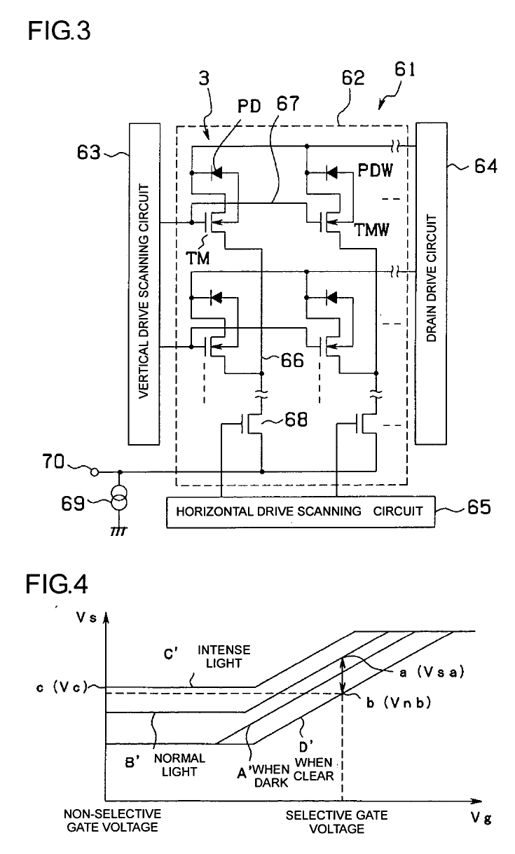

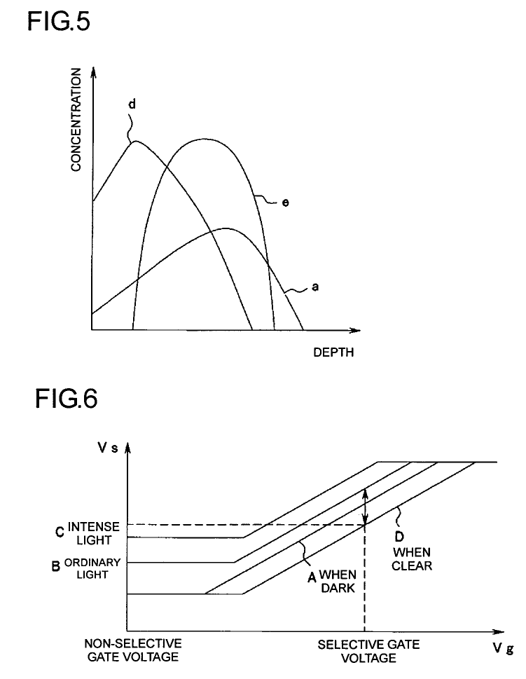

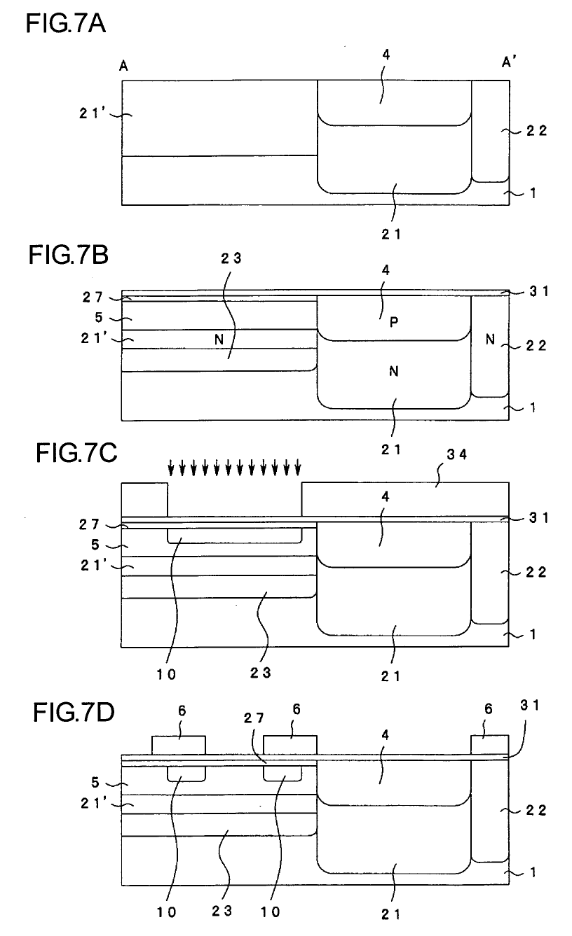

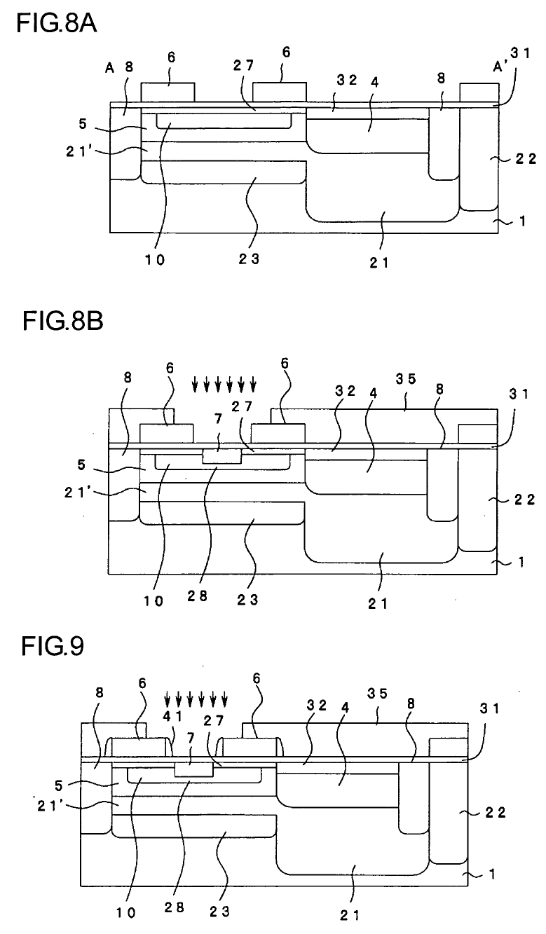

In the following, embodiments of the present invention are described with reference to the drawings. FIG. 1 to FIG. 8 concern the first embodiment of the present invention: FIG. 1 is a sectional view showing a sectional shape of a solid image pickup apparatus according to the present embodiment; FIG. 2 is a plan view of one sensor cell of a solid image pickup apparatus according to the present embodiment; and FIG. 3 is a circuit block diagram showing an entire structure of an element through an equivalent circuit. FIG. 4 is a graph for explaining the cause of generating a black smear. FIG. 5 is a graph for explaining a distribution of concentration in the source area and therebelow by taking substrate depth on the axis of abscissa and concentration of the impurity on the axis of ordinate. FIG. 6 is a graph showing characteristics of a modulation transistor in a solid image pickup apparatus according to the present embodiment. FIG. 7 and FIG. 8 are process diagrams for explaining a manufacturing process of an element.

Sensor Cell Structure

A solid image pickup apparatus according to the present embodiment has a sensor cell array in which sensor cells which are unit pixels are arrayed in a matrix pattern. Each sensor cell collects and stores light generating charges generated according to the input light and outputs a pixel signal of a level based on the collected light generating charges. By arraying sensor cells in a matrix pattern, an image signal of one screen may be obtained.

First, referring to FIG. 1 and FIG. 2, the structure of each sensor cell will be described. FIG. 2 shows one sensor cell. Also, the present embodiment shows an example of using a hole as a light generating charge. Even in a case of using an electron as the light generating charge, the construction is likewise possible. Note that FIG. 1 shows a sectional structure cut along line A-A′ of FIG. 2.

As the plan view of FIG. 2 shows, in a sensor cell 3 which is a unit pixel, there are installed a photo diode PD and a modulation transistor TM adjacently. As the modulation transistor TM, for example, an n-channel depression MOS transistor is used. The unit pixel is, for example, rectangular in shape.

In a photo diode forming area which is an opto-electrical element forming area, an opening area 2 is formed on the surface of a substrate 1, while a p-type well which is a wider area than the opening area 2 is located at a relatively shallow position on the substrate 1 surface, and there is formed a collection well 4 as the second well collecting light generating charges generated by the opto-electrical element. On the collection well 4, there is formed an n-type diffusion layer 32 as a pinning layer on the surface of the substrate 1.

Apart from the collection well 4 for a specified distance, there is formed on the modulation transistor TM forming area a well 5 for modulation, which is a p-type well, as a fourth well to control the modulation transistor TM as the light generating charges collected are transferred to the collection well 4.

On the well 5 for modulation, there is formed a gate (ring gate) 6 of a ring shape, while, in an area in the vicinity of the substrate 1 surface of a central opening of the ring gate 6, there is formed a source area 7 which is a high concentration n-type area. Around the ring gate 6, there is formed an n-type drain area 8. At a specified position of the drain area, there is formed an n⁺ layer drain contact area (not illustrated) in the vicinity of the substrate 1 surface.

The well 5 for modulation is what controls the threshold voltage of the channel of the modulation transistor TM. In the well 5 for modulation, there is formed below the ring gate 6 and the source area 7 a carrier pocket 10 (FIG. 1) which is a p-type high concentration area and which constitutes the first diffusion layer. The modulation transistor TM is constituted by the well 5 for modulation, the ring gate 6, the source area 7 and the drain area 8 such that corresponding to charges stored in the well 5 for modulation (carrier pocket 19), the threshold voltage of the channel changes.

As the drain area 8 and the diffusion layer 32 are biased to a positive potential by impressing the drain voltage, below the opening area 2 of the photo diode PD, a depletion layer spreads from a boundary between the diffusion layer 32 and the collection well 4 to the entire collection well 4, reaching the n-type well 21 which is the first well. On the other hand, from the boundary between the substrate 1 and the n-type well 21, the depletion layer spreads to the entire n-type well 21, reaching the collection well 4. In a depletion area, a light generating charge generates due to incident light through the opening 2. And, as mentioned above, the generated light generating charge is collected in the collection well 4.

The charge collected in the collection well 4 is transferred to the well 5 for modulation and held in the carrier pocket 10. By this means, the source potential of the modulation transistor TM becomes what corresponds to the quantity of charges transferred to the well 5 for modulation or the incident light to the photo diode PD.

Section of a Sensor Cell

Further, referring to FIG. 1, a sectional structure of the sensor cell 3 will be described in detail.

FIG. 1 shows the photo diode PD forming area and the modulation transistor TM forming area which constitute the unit pixel (cell). An isolation area 22 is provided between the photo diode PD forming area and the modulation transistor TM forming area which are adjacent cells.

At a relatively deep position of the substrate 1, there is formed an n-type well 21 over the entire area of the p-type substrate 1. On the n-type well 21 of the photo diode PD forming area, there is formed the p-type collection well 4. At the substrate surface side on the collection well 4, there is formed the n-type diffusion layer 32 which is a pinning layer. The n-type well 21 is formed to a relatively deep position of the substrate.

On the other hand, in the modulation transistor TM forming area, there is formed a p-type embedded layer 23 on the substrate 1. An n-type well 21′ constituting the third well with the p-type embedded layer 23 is limited to a relatively shallow position of the substrate. On the n-type well 21′ on the p-type embedded layer 23, there is formed the p-type well 5 for modulation. In the well 5 for modulation, the carrier pocket 10 due to p⁺ diffusion is formed below the ring gate 6 and the entire area surrounded by the ring gate 6.

In the modulation transistor TM forming area, the ring gate 6 is formed through a gate oxide film 31, and on the substrate surface below the ring gate 6, an n-type diffusion layer 27 constituting a channel is formed. On the substrate of the central opening of the ring gate 6, an n⁺ diffusion layer is formed, constituting the source area 7. It should be noted that part of the center of the air pocket 10 is eroded by the source area 7. Further, on the substrate surface around the ring gate 6, an n-type diffusion layer is formed, constituting the drain area 8. The n-type diffusion layer 27 constituting the channel is connected to the source area 7 and the drain area 8.

In the present embodiment, as mentioned above, below the ring gate 6 and the entire area surrounded by the ring gate 6, there is formed the carrier pocket 10, and even after formation of the source area 7, part of the center of the carrier pocket 10 remains in an area 28 below the source area 7. As a result of the central portion of the carrier pocket 10 remaining below the source area 7, a p-type layer below the source area 7 remains without being eroded by the source area 7. Namely, a p-type concentration of the area 28 below the source area is set high to raise the potential barrier against electrons. Also, since the carrier pocket 10 remains below the source area 7, it is possible to prevent formation of the junction FET due to a difference in the distribution of concentration in the area below the source area 7.

Circuit Configuration of the Entire Apparatus

Next, referring to FIG. 3, circuit configuration of a solid image pickup apparatus as a whole according to the present embodiment will be described.

A solid image pickup apparatus 61 has a sensor cell array 72 including the sensor cell 3 of FIG. 2 as well as circuits 63-65 driving each sensor cell 3 in the sensor cell array 62. The sensor cell array 62 is constituted by arranging the cell 3 in a matrix pattern. The sensor cell array 62 includes, for example, the cell 3 of 640×480 and an area (OB area)for optical black (OB). If the OB area is included, the sensor cell array is constituted by, for example, the cell 3 of 712×500.

Each sensor cell 3 includes the photo diode PD carrying out photoelectric conversion and the modulation transistor TM for detecting and reading optical signals. The photodiode PD generates an electric charge (light generating charge) corresponding to input light and the generated charge is collected in the collection well 4 ((connecting point PDW in FIG. 3). The light generating charge collected in the collection well 4 is transferred to and held in the air pocket 10 in the well 5 for modulation (comparable to connecting point TMW in FIG. 3) for threshold modulation of the modulation transistor TM.

The modulation transistor TM becomes equivalent to a change in back gate bias caused by the light generating charge being held in the carrier pocket 10, and the threshold voltage of the channel changes corresponding to the quantity of charge in the carrier pocket 10. As a result of this, the source voltage of the modulation transistor becomes what corresponds to the charge in the carrier pocket 10, that is, what corresponds to brightness of the incident light of the photo diode PD.

In this manner, each cell 3 carries out operations such as storage, transfer, read-out, and discharge as a drive signal is impressed on the ring gate 6, the source area 7, and the drain area 8 of the modulation transistor TM. As shown in FIG. 3, it is designed in each section of the cell 3 such that a scanning signal is supplied from the vertical drive scanning circuit 63, the drain drive circuit 64, and the horizontal drive scanning circuit 65. The vertical drive scanning circuit 63 supplies the scanning signal to each row of the gate line 67, while the drain drive circuit 64 impresses the drain voltage on each column of the drain area 8. Further, the horizontal drive scanning circuit 65 supplies the scanning signal to a switch 68 connected to each source line 66.

Each cell 3 is provided corresponding to a point of intersection of a plurality of source lines 66 arrayed in the horizontal direction of the sensor cell array 62 and a plurality of gate lines 67 arrayed in the vertical direction thereof. Each cell 3 of each line arrayed in the horizontal direction is connected to the gate line 67 having the common ring gate 6 of the modulation transistor TM, while each cell 3 of each column arrayed in the vertical direction is connected to the source line 66 having the common source of the modulation transistor TM.

As an “on” signal (selective gate voltage) is supplied to one of the plurality of the gate lines 67, each cell commonly connected to the gate line 67 to which the “on” signal is supplied is simultaneously selected, and from each source of these selected cells, a pixel signal is outputted through each source line 66. The vertical drive scanning circuit 63 supplies the “on” signal to the gate line 67 while sequentially shifting the “on” signal during a period of one frame. The pixel signal from each cell of the line to which the “on” signal is supplied is read simultaneously in one line portion from each source line 66 and supplied to each switch 68. The one line portion of the pixel signal is sequentially outputted (line output) per pixel by the horizontal drive scanning circuit 65 from the switch 68.

The switch 68 connected to each source line is connected to a video signal output terminal 70 through a common constant-current source (load circuit) 69. The source of the modulation transistor TM of each sensor cell 3 is connected to the constant-current source 69, thus constituting a source follower circuit of the sensor cell 3.

Operation

In the above-mentioned apparatus of JP '085, also, it is designed such that by controlling a voltage to be impressed on a gate of the modulation transistor according to a selected row and a non-selected row through common connection of source areas of all modulation transistors of the same column, a source voltage of the modulation transistor of the desired column may be detected. Namely, with respect to all pixels of the selected row, a potential (Vg) of the gate electrode is set high with a potential (Vg) of the gate electrode of the non-selected row as ground potential.

Further, due to scattering of each unit pixel and elimination of various noises, in a read operation, following a read operation of an optical signal of the selected row while a state of providing a potential to a pixel of the non-selected row is left as it is, the pixel of that selected row is initialized and subsequently the threshold voltage in the initialized state is read out. Then, a signal of a difference between the threshold voltage corresponding to the quantity of light generating charges and the threshold voltage in the initialized state is calculated, and a net optical signal component is outputted as the video signal.

Read-out processing in the apparatus of JP '085 will be described with reference to FIG. 4 showing the characteristics of the modulation transistor TM. Characteristics A′-D′ of FIG. 4 respectively show the characteristics of the modulation transistor TM when dark, when normal light is incident, when extremely intense light is incident, and when clear.

In FIG. 4, points a and b respectively show a level of a pixel signal based on a pixel of the selected row when incident light of a normal level enters and a level of a pixel signal due to a noise component after its initialization Vsa and Vab. Further, point c shows a level Vc of a pixel signal based on a pixel of a non-selected row when extremely bright incident light enters. In a case where light of normal intensity enters, as a pixel signal of a pixel of the selected row, a signal whose level is (Vsa−Vnb) (range of arrows) is obtained.

Now, in a specified column, suppose that incident light of the normal level enters to a pixel of the selected row and extremely bright light enters to one of the pixels of the non-selected row. A level of the pixel signal prior to the initialization based on the pixel of the selected row becomes Vsa. However, a level Vnb of the pixel signal after the initialization of the selected row is lower than a level Vc of the pixel signal based on the pixel of the non-selected row when extremely intense light enters. Since in the same column, the source areas are commonly connected, at the time of reading out after the initialization, a higher level Vc may be obtained as a level of the pixel signal after the initialization. Namely, as the pixel signal of the pixel of the selected row, a signal whose level is (Vsa−Vc) is outputted. (Vsa−Vc) is a relatively small value, and a display based on this pixel signal output becomes black. Until the initialization of the pixel when extremely intense light enters, the output of each pixel connected to the source line 66 becomes all relatively small value, and a screen display becomes the black smear in the vertical direction.

On the other hand, in the present embodiment, by forming the carrier pocket 10 also below the source area 7, it is adapted such that generation of the black smear when intense light enters may be prevented.

First, light detection and collecting operation of the light generating charge of the photo diode PG of the sensor cell 3 as well as a read-out operation of the modulation transistor TM will be described.

A low gate voltage is impressed on the ring gate 6 of the modulation transistor TM and a voltage (VDD) of, for example, approximately 2-4V necessary for transistor operation is impressed on the drain area 8. This will cause the n-type well 21 to be depleted. Further, an electric field generates between the drain area 8 and the source area 7.

Light entering through the opening area 2 of the photo diode PD enters the depleted n-type well 21, generating a pair of electron-hole (light generating charge). The p-type collection well 4 is, as a result of introduction of a high concentration impurity, such that its potential is low, whereas a light generating charge generating in the n-type well 21 is collected in the collection well 4. Further, the light generating charge is transferred from the collection well 4 to the well 5 for modulation in the modulation transistor forming area and stored in the carrier pocket 10.

By the light generating charge store d in the carrier pocket 10, the threshold voltage of the modulation transistor TM changes. In this condition, a gate voltage of, for example, approximately 2-4 V (selective gate voltage) is impressed on the ring gate 6 of the selected pixel, and a voltage VDD of, for example, approximately 2-4V is impressed on the drain area 8. Further, a constant current is run in the source area 7 of the modulation transistor TM by means of the constant-current source 69. This enables the modulation transistor TM to form a source follower circuit, and the source potential changes following fluctuation of the threshold voltage of the modulation transistor TM due to the light generating charge, so that the output voltage changes. Namely, an output corresponding to incident light is obtained.

At the time of the initialization, charges remaining in the carrier pocket 10, the collection well 4 and the well 5 for modulation are discharged. For example, a high positive voltage of 7-8V is impressed in the drain area 8 and the ring gate 6 of the modulation transistor TM. Thickness of the n-type well 21′ below the well 5 for modulation is thin. Also, on the substrate facing the n-type well 21′, there is formed a high concentration p-type embedded layer 23, so that an effect due to the voltage impressed on the ring gate 6 operates only on the well 5 for modulation and its adjacent area. Namely, a drastic potential change occurs in the well 5 for modulation, whereas an electric field strong enough to sweep the light generating charge out to the substrate 1 side is impressed mainly on the well 5 for modulation, causing any remaining light generating charge to be discharged with certainty to the substrate 1 by a low reset voltage.

After the initialization, a non-selective gate voltage of a relatively low voltage value is impressed on a ring gate of a non-selected pixel, while a selective gate voltage of a relatively high voltage value is impressed on the ring gate 6 of the selected pixel. And, from the source line 66 commonly connected, a signal output after the initialization of the selected pixel is obtained.

In the present embodiment, there is also formed the carrier pocket 10 below the source area 7. Through this carrier pocket 10, the area 28 below the source area 7 is maintained at a sufficiently high concentration. Namely, the p-type concentration will not greatly drop due to the source area 7. This enables a sufficiently high potential barrier to be formed below the source area 7. Also, below the source area 7, there is the high concentration p-type carrier pocket 10, and a junction FET will not be formed. This will not result in forming a current path from the n-type well 21′ to the source area 7.

FIG. 5 is for explaining a distribution of concentration in the source area and therebelow. The curve a in FIG. 5 shows a distribution of impurity concentration through injection of the impurity at the time of forming the p-type well 5. The curve a shows that the injection of the impurity was made to a depth corresponding to the p-type well 5 forming position slightly apart from the substrate surface.

The curve d shows a distribution of impurity concentration through injection of the impurity at the time of forming the source area 7. Ion implantation is performed so as to form the source area 7 in the vicinity of the substrate surface. The ion implantation at the time of forming the source area diffuses the impurity to a relatively deep area. The curve e shows a distribution of impurity concentration through injection of the impurity at the time of forming the carrier pocket 10. The ion implantation at the time of forming the carrier pocket 10 makes it possible to obtain a relatively high impurity concentration down to the area 28 below the source area 7.

Namely, by forming the carrier pocket 10 also below the source area 7, the impurity concentration in the area 28 below the source area 7 becomes high. That is, erosion of the well 5 for modulation is prevented by the source area 7. The impurity concentration in the area 28 below the source area 7 is high so that a sufficiently high potential barrier against electrons is constructed.

Further, any change in the concentration distribution in the horizontal direction in the area 28 below the source area 7 is small, so the junction FET will not be formed. In this manner, the transistor characteristics of the modulation transistor TM may be improved.

FIG. 6 shows the transistor characteristics in the present embodiment. Characteristic A of FIG. 6 shows a Vg (gate electrode) −Vs (source voltage) characteristic when it is dark, characteristic B shows a V−Vs characteristic when normal light is incident, characteristic C shows a Vg−Vs characteristic when extremely intense light is incident, and characteristic D shows a Vg−Vs characteristic when it is clear.

The sufficiently high potential barrier is obtained in the area 28 below the source area 7 by the carrier pocket 10 formed down to below the source area 7. Also, since the junction FET is not formed below the source area 7, a leak current path from the n-type well 21′ to the source area 7 is not formed, thereby providing the modulation transistor TM with an excellent Vg−Vs characteristic in relative linearity even in a range of relatively low gate voltages.

As shown in FIG. 6, even in case of a non-selective pixel on which intense light is incident, when a sufficiently low non-selective gate voltage is incident, the output level of a pixel signal becomes lower than the pixel signal level of a selective pixel after the initialization. By this means, even when each pixel of the same column is connected to the common source line 66, it is possible to obtain a pixel signal gained from the selective pixel as the pixel signal before and after the initialization by impressing a sufficiently high selective voltage on the ring gate 6 of the modulation transistor TM. Namely, even when extremely intense light enters, in the same way as when light of normal brightness enters, it becomes possible to obtain a signal before and after the initialization based on the selective pixel, thereby making it possible to output a normal pixel signal corresponding to the quantity of incident light and prevent generation of the black smear.

Process

Next, referring to process diagrams in FIG. 7 and FIG. 8, the manufacturing process of an element will be described. FIG. 7 and FIG. 8 shows a section at a position along cut line A-A′ of FIG. 2. In FIG. 7 and FIG. 8, arrows on the substrate show that ion implantation is performed.

On a P substrate 1 that is prepared, an isolation area 22 for element separation is formed by using a specified photoresist mask as shown in FIG. 7 A. Next, using the specified photoresist mask, for example, a phosphor (P) ion is implanted to form the n-type well 21 in the photo diode forming area and the n-type well 21 in the modulation transistor forming area. This ion implantation is performed down to a relatively deep position as far as the photo diode forming area is concerned. Next, using the specified photoresist mask, the p-type collection well 4 is formed on the substrate 1 surface side of the photo diode forming area, for example, by performing the ion implantation of boron. Also, the gate oxide film 31 is formed on the substrate 1 surface by thermal oxidation.

Next, using the specified photoresist mask, a p-type impurity is subjected to deep ion implantation in the modulation transistor forming area, thereby forming the p-type embedded layer 23. Further, using the same photoresist mask, a p-type impurity is subjected to shallow ion implantation, thereby forming the n-type diffusion layer 27 to obtain a channel of the modulation transistor TM in the vicinity of the substrate surface on the carrier pocket 10.

Next, as shown in FIG. 7 C, there is formed a photoresist 34 covering an area other than an area slightly inside the perimeter of the ring gate 6, and through injection of the impurity with this photoresist 34 as a mask, there is formed the carrier pocket 10 due to the high concentration p⁺ diffusion layer in the well 5 for modulation for the entire range below the area surrounded by the gate ring 6. Next, as shown in FIG. 7 D, on the gate oxide film 31, there is formed the ring gate 6 of the modulation transistor TM.

Next, as shown in FIG. 8 A, with an un-illustrated photoresist mask covering the photo diode forming area and the ring gate 6 as a mask, an n-type impurity is subjected to ion implantation to form the drain area 8. Also, on the substrate surface in the photo diode forming area, there is formed the n-type diffusion layer 32.

Next, as shown in FIG. 8 B, the photoresist mask 35 covering the photo diode forming area is formed, and using phosphor with the photoresist mask 35 and the ring gate 6 as a mask, an n⁺ impurity injection is carried out to form the source area 7.

In the present embodiment, at the time of forming the source area 7, even if phosphor should diffuse down to below the source area 7, by means of the high concentration p-type carrier pocket 10, the area 28 below the source area 7 maintains the sufficiently high concentration p-type.

In this manner, according to the present embodiment, without increasing the number of processing steps, the potential barrier below the source area 7 is made high, while, at the same time, generation of a junction transistor constituting the leak path may be prevented.

Effects of the Embodiment

In this manner, in the present embodiment, through formation of the carrier pocket 10 below the source area 7, formation of the leak current path between the n-type well 21′ and the source area 7 is prevented. Also, by setting high concentration of the p-type impurity of the area 28 below the source area 7 in the well 5 for modulation which can be the leak path between the source and the drain, it is possible to make it difficult for the leak current to generate. This makes it possible to prevent generation of the black smear and improve the picture quality.

Second Embodiment

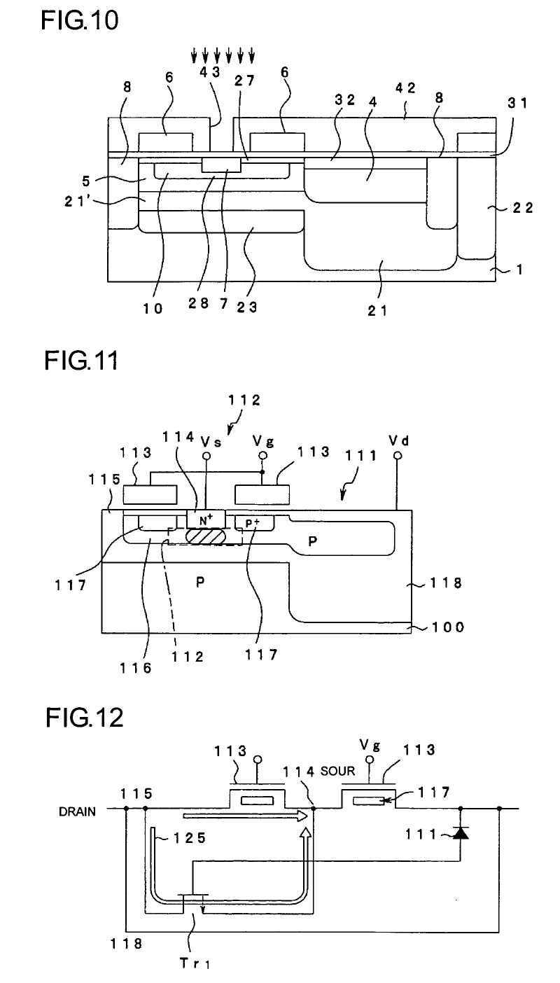

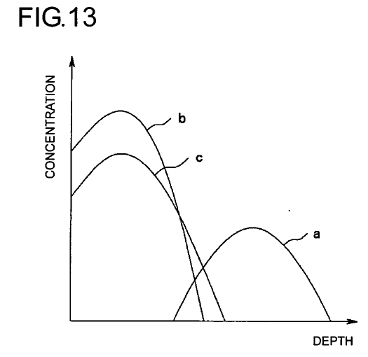

FIG. 9 and FIG. 10 are explanatory diagrams for explaining the manufacturing process according to a second embodiment of the present invention. In FIG. 9 and FIG. 10, like composing elements as FIG. 8 are attached with like reference numerals.

In the manufacturing process of FIG. 8, an example of forming the source area 7 after formation of the ring gate was explained. However, the source area 7 may be formed after sidewall formation or after contact etching.

FIG. 9 illustrates an example of forming the source area 7 after sidewall formation.

A sidewall 41 is formed on a sidewall of the ring gate 6 through formation of an un-illustrated insulating film covering the ring gate 6 as well as isotropic etching with respect to the insulating film. Also, on a portion other than the ring gate 6 including the sidewall 41, there is formed the photoresist mask 35 covering the photo diode forming area. With the ring gate 6 including the photoresist mask 35 and the sidewall as a mask, n⁺ impurity injection using phosphor is carried out, thereby forming the source area 7.

FIG. 1 illustrates an example of forming the source area 7 after contact hole opening.

After the ring gate 6 (refer to FIG. 7 D) is formed, an interlayer insulating film 42 is formed over the entire space of the modulation transistor forming area and the photo diode forming area. Next, to make contact between an un-illustrated wiring layer to be formed on the interlayer insulating film 42 and the source area 7, a hole is made, through etching, of the interlayer insulating film 42 at a position comparable to the source area to form a contact hole 43.

Next, with the interlayer insulating film 42 as a mask, through the contact hole 43, an n⁺ impurity injection using phosphor is carried out, thereby forming the source area 7.

Other configuration and operation are the same as the first embodiment. In the present embodiment, too, the same effect as the first embodiment may be attained.

1. A solid image pickup apparatus including an opto-electrical element and a transistor formed adjacent to the opto-electrical element, the solid image pickup apparatus comprising:
a single conductive type substrate;
a first well of an inverse conductive type formed on the substrate of an opto-electrical element forming area;
a second well of the single conductive type formed on the first well:
a third well of the inverse conductive type formed on the substrate of a forming area of the transistor and formed adjacent to the first well;
a fourth well of the single conductive type formed on the third well and formed adjacent to the second well;
a gate electrode formed over the fourth well, having an opening;
a source formed below the opening;
a drain formed apart from the source and electrically connected to the third well; and
a first diffusion layer of the single conductive type formed below the gate electrode and below the opening.

2. The solid image pickup apparatus according to claim 1, wherein:
the first diffusion layer constitutes a potential barrier of a current channel from the third well to the source.

3. The solid image pickup apparatus according to claim 1, wherein:
the first diffusion layer is formed in a concentration in excess of substantially the same concentration as the concentration of the third well.
